(19) United States
(12) Patent Application Publication
(10) Pub. No.: US 2025/0266272 A1
(43) Pub. Date: Aug. 21, 2025

(54) LASER PROCESSING APPARATUS AND METHOD FOR MANUFACTURING DISPLAY DEVICE USING THE SAME

(71) Applicant: Samsung Display Co., LTD., Yongin-si (KR)

(72) Inventors: WOOHYUN JUNG, Yongin-si (KR); KONSTANTIN MISHCHIK, Yongin-si (KR); HYUNGSIK KIM, Yongin-si (KR); CHEOLLAE ROH, Yongin-si (KR); JEKIL RYU, Yongin-si (KR); KISANG LEE, Yongin-si (KR); SEONGHO JEONG, Yongin-si (KR)

(73) Assignee: Samsung Display Co., LTD., Yongin-si (KR)

(21) Appl. No.: 18/975,066

(22) Filed: Dec. 10, 2024

(30) Foreign Application Priority Data
Feb. 21, 2024 (KR) 10-2024-0025376

(51) Int. Cl. H01L 21/67; B23K 26/06; B23K 26/21; G02B 27/09; H01L 21/268

(52) U.S. Cl. CPC H01L 21/67115; B23K 26/0648; B23K 26/21; H01L 21/268; G02B 27/0927

(57) ABSTRACT

A laser processing apparatus according to an embodiment may include a stage on which a processing target may be seated, a laser source that generates a first beam, a beam converter that transforms a spatial phase of the first beam that converts the first beam into a second beam, a scanner that changes a traveling direction of the second beam toward the processing target, and adjusts a traveling path of the second beam, a scan lens that adjusts a focal point of the second beam emerging from the scanner to focus the second beam on the processing target, and a stage moving part that moves the stage.

### CROSS-REFERENCE TO RELATED APPLICATION(S)

This application claims priority under 35 U.S.C. § 119 to and benefits of Korean Patent Application No. 10-2024-0025376 filed on Feb. 21, 2024 in the Korean Intellectual Property Office, the entire contents of which are incorporated herein by reference.

### BACKGROUND

### 1. Technical Field

Embodiments of the disclosure relate to a laser processing apparatus and a method for manufacturing a display device using the same.

### 2. Description of the Related Art

As information technology develops, the importance of display devices, which are connection media between users and information, is emerging. Accordingly, the use of display devices such as a liquid crystal display device, an organic light emitting display device, and a plasma display device is increasing.

The display device may include light emitting elements, and the light emitting elements may include an anode electrode, a cathode electrode, and a light emitting layer disposed between the anode electrode and the cathode electrode. A tandem light emitting element may have a structure in which at least two light emitting structures of hole transport layer/light emitting layer/electron transport layer are provided between the anode electrode and the cathode electrode, and a charge generation layer configured to assist in generating and moving charges may exist between the light emitting structures.

### SUMMARY

Embodiments of the disclosure provide a laser processing apparatus with reduced processing time.

Embodiments of the disclosure also provide a method for manufacturing a display device with improved a display quality and reduced a manufacturing cost and a manufacturing time.

Additional features of the inventive concepts will be set forth in the description which follows, and in part will be apparent from the description, or may be learned by practice of the inventive concepts.

A laser processing apparatus according to an embodiment of the disclosure may include a stage on which a processing target may be seated, a laser source that generates a first beam, a beam converter that converts the first beam into a second beam by transforming a spatial phase of the first beam, a scanner that changes a traveling direction of the second beam toward the processing target and that adjusts a traveling path of the second beam, a scan lens that focuses the second beam onto the processing target by adjusting a focal point of the second beam emerging from the scanner, and a stage moving part that moves the stage.

In an embodiment of the disclosure, the first beam may be a Gaussian beam having a circular shape. The second beam may pass through the scanner and the scan lens and onto a focal plane on the processing target in a form of a vortex beam having a ring shape.

In an embodiment of the disclosure, the first beam may be a Gaussian beam having a circular shape. The second beam may pass through the scanner and the scan lens and onto a focal plane on the processing target in a shape of a triangle with angled corners or a triangle with rounded corners.

In an embodiment of the disclosure, the beam converter may be configured to convert and split the first beam into a plurality of second beams.

In an embodiment of the disclosure, the stage moving part may move the stage while the scanner performs scanning to sequentially radiate the second beam onto different positions on the processing target.

A method for manufacturing a display device according to an embodiment of the disclosure may include forming a first electrode on a circuit layer to overlap each of first, second, and third emission areas, forming a pixel defining layer on the circuit layer and the first electrode, the pixel defining layer overlapping a non-emission area between the first, second, and third emission areas adjacent to each other, and the pixel defining layer having first, second, and third pixel openings that overlap the first, second, and third emission areas, respectively, forming a stacked structure in the first, second, and third pixel openings and on the pixel defining layer, the stacked structure including a first light emitting structure, a charge generation layer, and a second light emitting structure may be sequentially stacked on each other, forming a groove in the stacked structure that overlaps the non-emission area by radiating laser beams onto the stacked structure, and forming a second electrode on the stacked structure.

In an embodiment of the disclosure, the forming of the groove may include radiating ring-shaped laser beams onto the stacked structure.

In an embodiment of the disclosure, each of the ring-shaped laser beams may be radiated to overlap the non-emission area without overlapping the first, second, and third emission areas.

In an embodiment of the disclosure, each of the ring-shaped laser beams may be radiated to surround a corresponding one of the first, second, and third emission areas.

In an embodiment of the disclosure, the ring-shaped laser beams may be radiated to partially overlap each other.

In an embodiment of the disclosure, the forming of the groove may include forming preliminary grooves by radiating first laser beams having a shape of a triangle with angled corners or a triangle with rounded corners onto the stacked structure to overlap the non-emission area, and radiating second laser beams having a shape in which the first laser beam may be inverted onto the stacked structure to overlap the non-emission area.

In an embodiment of the disclosure, each of the first laser beams and the second laser beams may be radiated to overlap the non-emission area without overlapping the first, second, and third emission areas.

In an embodiment of the disclosure, each of the first laser beams may be radiated between the first, second, and third emission areas adjacent to each other.

In an embodiment of the disclosure, each of the second laser beams may be radiated between the first, second, and third emission areas adjacent to each other and between the preliminary grooves adjacent to each other.

In an embodiment of the disclosure, the first laser beams and the second laser beams may be radiated to partially overlap each other.

In an embodiment of the disclosure, the groove may have a mesh shape in a plan view.

In an embodiment of the disclosure, the groove may be formed through the first light emitting structure, the charge generation layer, and the second light emitting structure in a thickness direction.

In an embodiment of the disclosure, the groove may expose an upper surface of the pixel defining layer.

In an embodiment, wherein the at least one charge generation layer may include a plurality of charge generation layers, and the plurality of charge generation layers disposed in the first, second, and third emission areas adjacent to each other, respectively, may be physically separated from each other by the groove.

In an embodiment of the disclosure, each of the first light emitting structure and the second light emitting structure may include a light emitting layer.

According to embodiments of the disclosure, a lateral leakage between light emitting elements can be prevented, so that a display device with improved display quality can be manufactured. A manufacturing cost and a manufacturing time of the display device can be reduced.

It is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this specification, illustrate embodiments of the disclosure, and together with the description serve to explain the disclosure.

FIG. 1 is a view schematically showing a laser processing apparatus according to an embodiment of the disclosure.

FIGS. 2, 3, 4A, 4B, 4C, 4D, and 4E are views showing an example of a laser processing method using the laser processing apparatus of FIG. 1.

FIG. 5 is a view schematically showing a laser processing apparatus according to an embodiment of the disclosure.

FIGS. 6, 7A, 7B, and 7C are views showing an example of a laser processing method using the laser processing apparatus of FIG. 5.

FIG. 8 is a schematic plan view showing a display device according to an embodiment of the disclosure.

FIG. 9 is a sectional view showing the display device of FIG. 8.

FIG. 10 is a sectional view showing a light emitting element included in the display device of FIG. 9.

FIGS. 11A, 11B, 12, 13, and 14 are views showing an example of a method for manufacturing a display device according to an embodiment of the disclosure.

FIG. 15 is a view schematically showing a laser processing apparatus according to an embodiment of the disclosure.

FIGS. 16A, 16B, 17A, and 17B are views showing an example of a method for manufacturing a display device according to an embodiment of the disclosure.

FIGS. 18 and 19 are views schematically showing a laser processing apparatus according to an embodiment of the disclosure.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc., (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may be different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc., may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, parts, and/or modules. Those skilled in the art will appreciate that these blocks, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, parts, and/or modules being implemented by microprocessors or other similar hardware, they may be programmed and controlled using software (e.g., microcode) to perform various functions discussed herein and may optionally be driven by firmware and/or software. It is also contemplated that each block, part, and/or module may be implemented by dedicated hardware, or as a combination of dedicated hardware to perform some functions and a processor (e.g., one or more programmed microprocessors and associated circuitry) to perform other functions. Also, each block, part, and/or module of some embodiments may be physically separated into two or more interacting and discrete blocks, parts, and/or modules without departing from the scope of the inventive concepts. Further, the blocks, parts, and/or modules of some embodiments may be physically combined into more complex blocks, parts, and/or modules without departing from the scope of the inventive concepts.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Illustrative, non-limiting embodiments of the disclosure will be more clearly understood from the following detailed description in conjunction with the accompanying drawings.

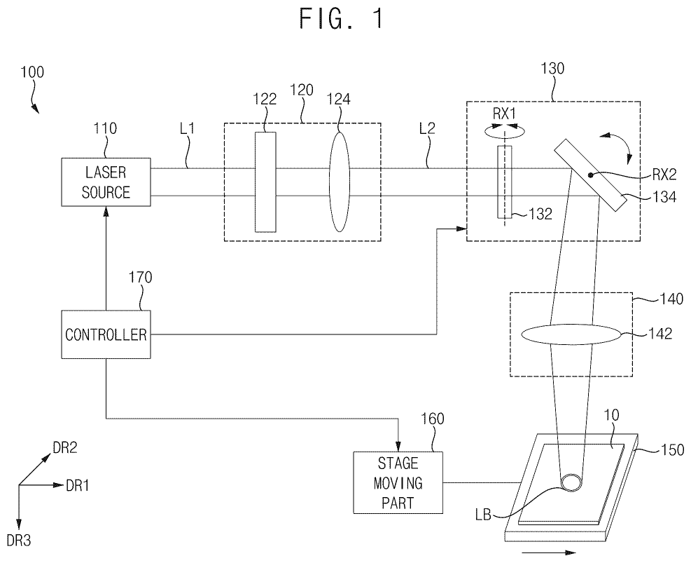

FIG. 1 is a view schematically showing a laser processing apparatus according to an embodiment of the disclosure.

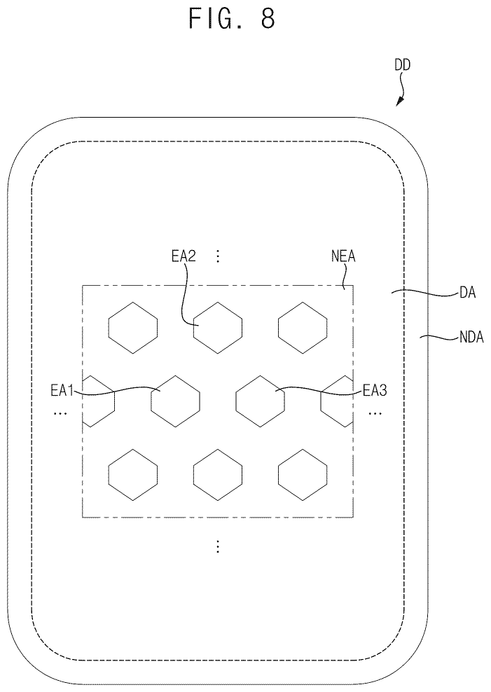

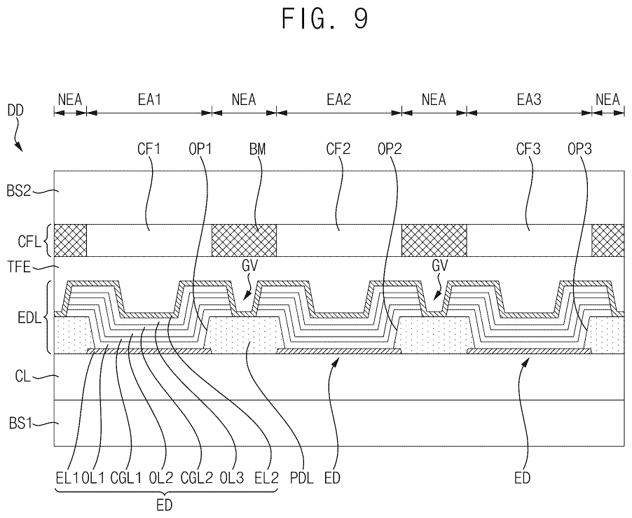

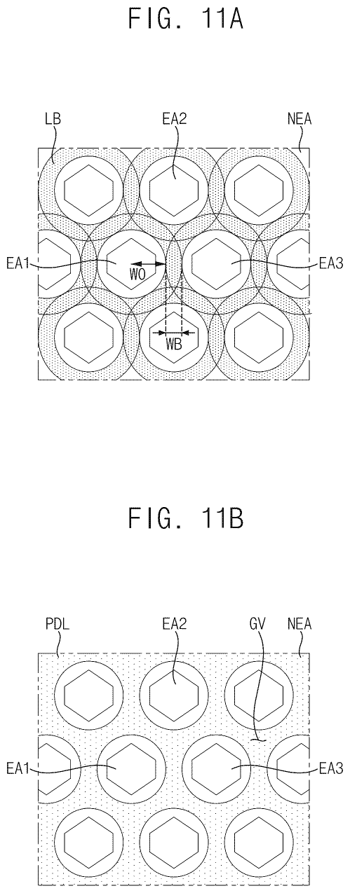

Referring to FIG. 1, according to an embodiment of the disclosure, a laser processing apparatus 100 may be an apparatus for manufacturing a display device DD (see FIGS. 8 and 9) that will be described below, and may be a laser processing apparatus used in a method for manufacturing a display device (see FIGS. 11A, 11B, 12, 13, and 14), which will be described below.

The display device manufactured by the laser processing apparatus 100 may be applied to various electronic devices including small and medium-sized electronic equipment such as a tablet PC, a smartphone, a vehicle navigation unit, a camera, a central information display (CID) provided in a vehicle, a wristwatch-type electronic device, a personal digital assistant (PDA), a portable multimedia player (PMP), and a game console, medium and large-sized electronic equipment such as a television, an external billboard, a monitor, a personal computer, and a laptop computer, and the like. These are presented only as examples, and the display device may be adopted in other electronic devices without departing from the concept of the disclosure.

According to an embodiment of the disclosure, the laser processing apparatus 100 may include a laser source 110, a beam converter 120, a scanner 130, and a scan lens 140. The laser source 110, the beam converter 120, the scanner 130, and the scan lens 140 may be arranged sequentially based on a traveling direction of a laser beam.

The laser processing apparatus 100 may process a processing target 10 by radiating a laser beam LB onto the processing target 10. The processing target 10 may be seated on a seating surface of a stage 150.

Hereinafter, for convenience of description, first to third (or first, second, and third) directions DR1, DR2, and DR3 will be defined. The first to third directions DR1, DR2, and DR3 may be orthogonal to each other. For example, the seating surface of the stage 150 may be substantially parallel to a plane defined by the first direction DR1 and the second direction DR2. The laser processing apparatus 100 may radiate the laser beam LB in the third direction DR3 toward the processing target 10. For example, each of the first direction DR1 and the second direction DR2 may be referred to as a horizontal direction, and the third direction DR3 may be referred to as a vertical direction. In case that the third direction DR3 is a downward direction, the laser processing apparatus 100 may be a bottom-up laser processing apparatus. Conversely, in case that the third direction DR3 is an upward direction, the laser processing apparatus 100 may be a top-down laser processing apparatus. The top-down laser processing apparatus may be advantageous for collecting and removing particles generated from the processing target 10.

The laser source 110 may be various laser generation devices. The laser source 110 may generate and emit a first beam L1. The laser source 110 may emit the first beam L1 continuously or discontinuously. A laser wavelength, a pulse duration, pulse energy, and the like of the first beam L1 may be adjusted by the laser source 110.

According to an embodiment of the disclosure, the first beam L1 may have a wavelength in a range of about 224 nm to about 355 nm, a pulse duration in a range of about 290 fs to about 5 ps, and pulse energy in a range of about 0.01 μJ to about 100 μJ, but since such a configuration is provided for illustrative purposes, the disclosure is not limited thereto. In case that the wavelength of the first beam L1 is greater than about 355 nm, it may be difficult to reduce a size of the laser beam LB that reaches the processing target 10 to a required size. In case that the pulse duration of the first beam L1 is greater than about 5 ps, a processing surface may become irregular.

The laser source 110 may emit a single beam, or may emit multiple multi-beams. Hereinafter, the description will focus on an example in which the first beam L1 may be a single beam.

The first beam L1 emitted from the laser source 110 may be a Gaussian beam having a circular shape. The beam converter 120 may transform a spatial phase of the first beam L1, which is a Gaussian beam having a circular shape, to convert the first beam L1 into a second beam L2 having an appropriate spatial phase. The second beam L2 may have an appropriate spatial phase to pass through the scanner 130 and the scan lens 140 and finally radiated onto a focal plane on the processing target 10 in the form of a vortex beam (or ring-shaped beam or annular beam) having a ring shape (the laser beam LB in FIG. 1).

According to an embodiment of the disclosure, the beam converter 120 may include a diffractive optical element (DOE) 122, and a relay lens 124. The diffractive optical element 122 may be configured to diffract the first beam L1, which is a Gaussian beam having a circular shape, to convert the first beam L1 into the second beam L2 having the spatial phase. The relay lens 124 may relay the second beam L2 to the scanner 130.

According to an embodiment of the disclosure, the diffractive optical element 122 may be replaced with a spatial light modulator (SLM). The spatial light modulator may be configured to adjust at least one of an intensity and a phase of the first beam L1, which is a Gaussian beam having a circular shape, to convert the first beam L1 into the second beam L2 having the spatial phase.

The second beam L2 may be incident on the scanner 130. The scanner 130 may determine a traveling direction of the incident beam. For example, the scanner 130 may change a traveling direction of the second beam L2 exiting (or emerging) from the beam converter 120 toward the processing target 10. The scanner 130 may be a type of galvanometer scanner or galvo scanner.

According to an embodiment of the disclosure, the scanner 130 may include two mirrors having different rotational axes. For example, the scanner 130 may include a first mirror 132 and a second mirror 134. Each of the first mirror 132 and the second mirror 134 may be a type of galvanometer mirror or galvo mirror.

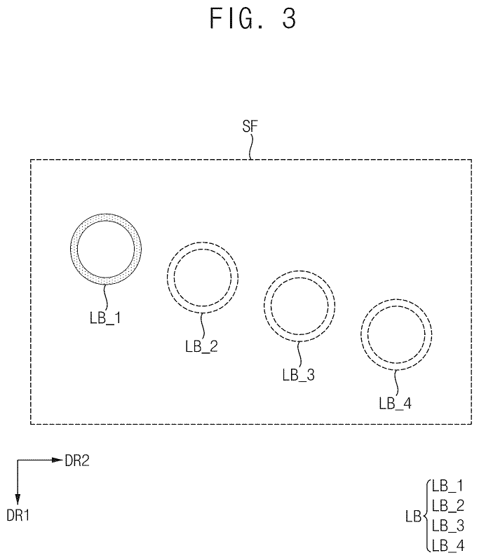

Since the scanner 130 includes the two mirrors having different rotational axes, a traveling path of the second beam L2 may be changed. Accordingly, the scanner 130 may implement a scanning field (SF in FIG. 3) having a 2D shape on the processing target 10.

The 2D shape may refer to a unit shape of a surface defined by a combination of two different directions, rather than a straight line defined by only a direction. For example, the 2D shape may refer to a shape of a figure such as a circle or a rectangle. The scanning field may refer to an area in which scanning is performed by radiating a laser beam onto the processing target 10. For example, the scanning field may be parallel to a plane defined by the first direction DR1 and the second direction DR2.

The first mirror 132 and the second mirror 134 may have different rotational axes. For example, the first mirror 132 may rotate about a first rotational axis RX1 that is parallel to the third direction DR3, and the second mirror 134 may rotate about a second rotational axis RX2 that is parallel to the second direction DR2. The scanner 130 may change an angle of at least one of the first mirror 132 and the second mirror 134 to variously adjust a traveling path of the laser beam in the scanning field on the processing target 10.

The second beam L2 that has passed through the scanner 130 to have a changed path may be incident on the scan lens 140. The scan lens 140 may include one or multiple lenses 142. The scan lens 140 may adjust a focal point of the second beam L2 emerging from the scanner 130 to focus the second beam L2 on the scanning field on the processing target 10.

The second beam L2 emerging from the scanner 130 may be converted into the laser beam LB while passing through the scan lens 140. The laser beam LB emerging from the scan lens 140 may reach the processing target 10. The laser beam LB radiated to the focal plane on the processing target 10 may be a vortex beam having a ring shape (see FIG. 3).

The processing target 10 may be seated on the seating surface of the stage 150. For example, the seating surface of the stage 150 may be substantially parallel to a plane defined by the first direction DR1 and the second direction DR2. The stage 150 may be moved in a direction (e.g., predetermined or selectable direction) by the stage moving part 160.

The controller 170 may control overall operations of the laser source 110, the scanner 130, and the stage moving part 160. For example, the laser source 110 may receive a first control signal from the controller 170 to adjust an output, a wavelength, and the like of the first beam L1. The scanner 130 may receive a second control signal from the controller 170 to adjust the traveling path of the second beam L2. The stage moving part 160 may receive a third control signal from the controller 170 to transfer the processing target 10 in a designated direction.

According to an embodiment of the disclosure, the stage 150 may be moved in a direction (e.g., predetermined or selectable direction) by the stage moving part 160 while the scanner 130 performs the scanning to sequentially radiate laser beams onto various positions on the scanning field. Accordingly, the laser processing apparatus 100 may reduce a processing time of the processing target 10.

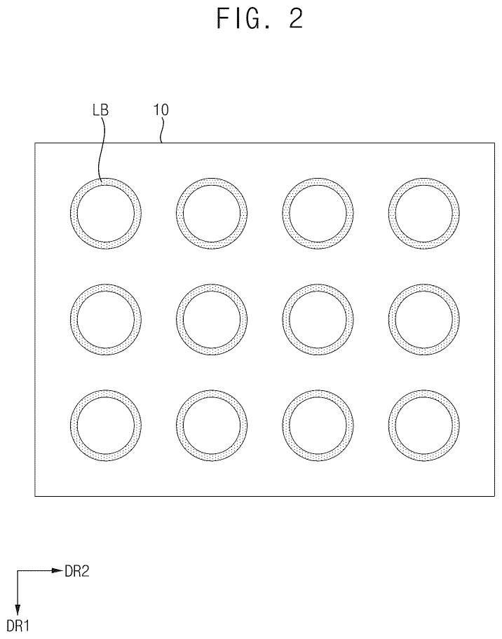

FIGS. 2, 3, 4A, 4B, 4C, 4D, and 4E are views showing an example of a laser processing method using the laser processing apparatus of FIG. 1.

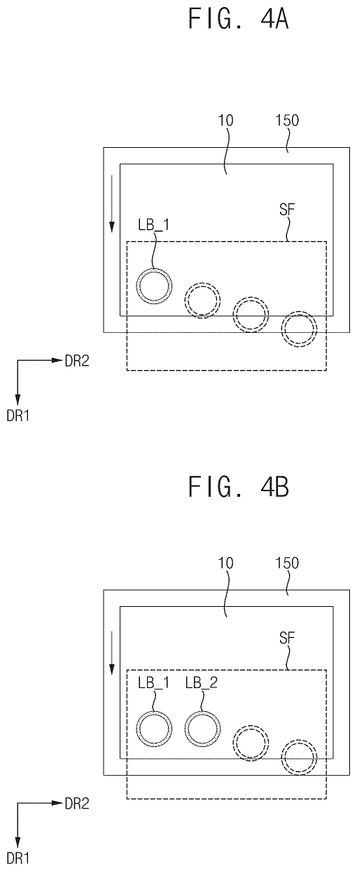

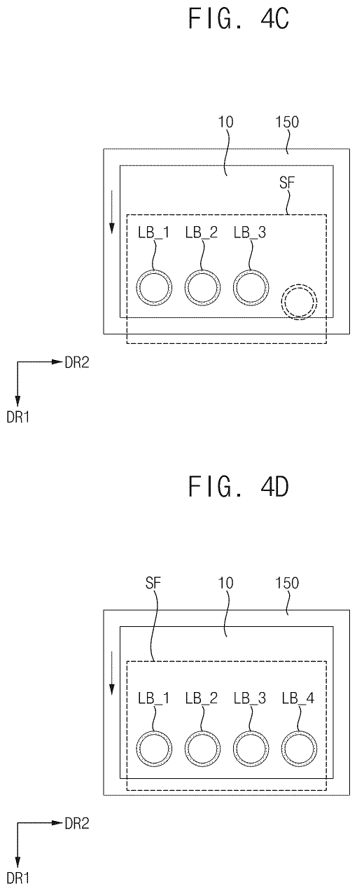

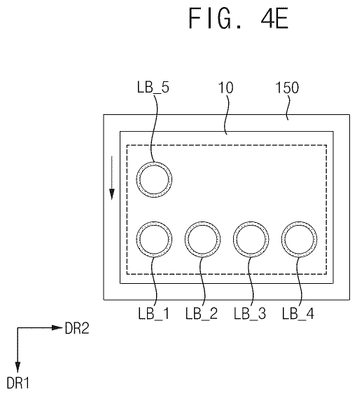

For example, FIG. 2 may show a shape of the processing target 10 after being processed, which is obtained by patterning the processing target 10 by radiating ring-shaped laser beams LB onto the processing target 10. FIGS. 3, 4A, 4B, 4C, 4D, and 4E may show an example of a laser processing method for implementing the shape of the processing target 10 after being processed, which is shown in FIG. 2, by using the laser processing apparatus 100 of FIG. 1. Although laser beams LB have been shown in FIG. 2 as being radiated while being spaced apart from each other in the first direction DR1 and the second direction DR2, such a configuration is provided for illustrative purposes, and the laser beams LB may be set to be radiated in various arrangements as needed. For example, as shown in FIG. 11A, the laser beams LB may be radiated to partially overlap each other.

Referring to FIGS. 2, 3, 4A, 4B, 4C, 4D, and 4E, according to an embodiment of the disclosure, the stage 150 may be moved in a direction (e.g., predetermined or selectable direction) by the stage moving part 160 while the scanner 130 performs the scanning to sequentially radiate laser beams LB_1, LB_2, LB_3, and LB_4 to different positions in the scanning field SF. For example, the controller 170 may control the stage moving part 160 such that the stage 150 may be moved at a constant speed in the first direction DR1.

The controller 170 may control the scanner 130 to adjust the traveling path of the laser beam LB in the scanning field SF in consideration of the movement of the stage 150. The controller 170 may control the output of the first beam L1 of the laser source 110 such that the laser beam LB may be radiated only to desired positions in the scanning field SF.

For example, as shown in FIG. 3, the scanner 130 may adjust the traveling path of the laser beam LB such that the laser beams LB_1, LB_2, LB_3, and LB_4 may be sequentially radiated in a diagonal direction between the first direction DR1 and the second direction DR2 in the scanning field SF in consideration of a movement speed of the stage 150 in the first direction DR1. Accordingly, as shown in FIGS. 4A, 4B, 4C, 4D, and 4E, the laser beams LB_1, LB_2, LB_3, and LB_4 may be radiated onto the processing target 10 in parallel with each other in the second direction DR2 as intended.

According to an embodiment of the disclosure, after the laser beam LB_4 has radiated, as shown in FIG. 4E, the scanner 130 may radiate a laser beam LB_5 such that the laser beam LB_5 may be adjacent to the laser beam LB_1. Next, the scanner 130 may sequentially radiate laser beams in a diagonal direction between the first direction DR1 and the second direction DR2 in the scanning field SF. The laser processing apparatus 100 may process the processing target 10 in the shape shown in FIG. 2 by repeatedly performing the process described above.

According to embodiments of the disclosure, the stage 150 may be moved in a direction (e.g., predetermined or selectable direction) by the stage moving part 160 while the scanner 130 performs the scanning to sequentially radiate laser beams to various positions on the scanning field. Therefore, a processing time of the processing target 10 may be reduced.

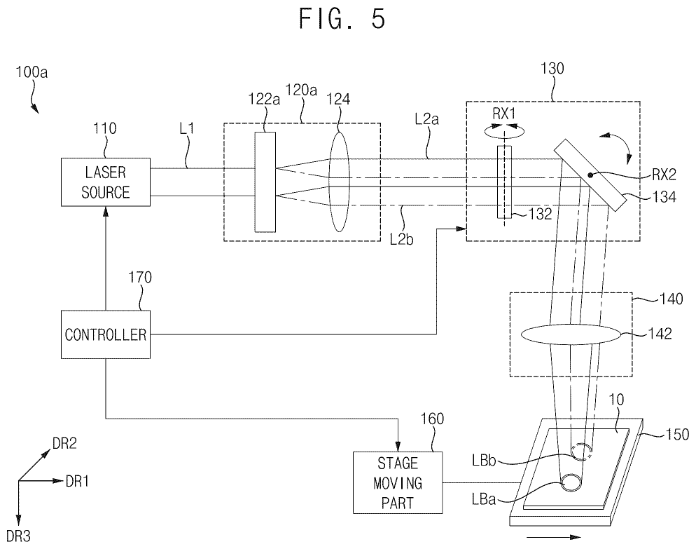

FIG. 5 is a view schematically showing a laser processing apparatus according to an embodiment of the disclosure.

A laser processing apparatus 100a of FIG. 5 may be substantially identical to the laser processing apparatus 100 of FIG. 1 except for a configuration of a diffractive optical element 122a. Therefore, redundant descriptions will be omitted or simplified.

Referring to FIG. 5, according to an embodiment of the disclosure, a laser processing apparatus 100a may include a laser source 110, a beam converter 120a, a scanner 130, and a scan lens 140.

A first beam L1 emitted from the laser source 110 may be a Gaussian beam having a circular shape. The first beam L1 may be a single beam.

The beam converter 120a may convert the first beam L1, which is a Gaussian beam having a circular shape, to have an appropriate spatial phase while splitting the first beam L1 into multiple second beams L2a and L2b. In other words, each of the second beams L2a and L2b split by the beam converter 120a may have an appropriate spatial phase to pass through the scanner 130 and the scan lens 140 and finally radiated to a focal plane on a processing target 10 in the form of a vortex beam having a ring shape (laser beams LBa and LBb in FIG. 5).

According to an embodiment of the disclosure, the beam converter 120a may include a diffractive optical element 122a and a relay lens 124. The diffractive optical element 122a may be configured to diffract the first beam L1, which is a Gaussian beam having a circular shape, to convert and split the first beam L1 into the second beams L2a and L2b, each of which has the spatial phase. Although the diffractive optical element 122a has been shown in FIG. 5 as splitting the first beam L1 into two second beams L2a and L2b, the diffractive optical element 122a may split the first beam L1 into at least three second beams. For example, the diffractive optical element 122a may split the first beam L1 into two to eight second beams. According to an embodiment of the disclosure, the diffractive optical element 122a may be replaced with a spatial light modulator (SLM). The relay lens 124 may relay the second beams L2a and L2b converted into vortex beams to the scanner 130.

The second beams L2a and L2b may be incident on the scanner 130. The scanner 130 may variously adjust traveling paths of the laser beams in a scanning field.

The second beams L2a and L2b that have passed through the scanner 130 to have changed paths may be incident on the scan lens 140. The scan lens 140 may adjust focal points of the second beams L2a and L2b emerging from the scanner 130 to focus the second beams L2a and L2b onto the scanning field on the processing target 10.

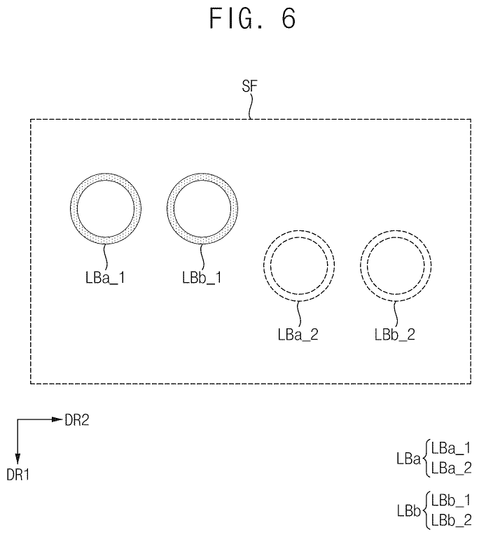

The second beams L2a and L2b emerging from the scanner 130 may be converted into laser beams LBa and LBb, respectively, while passing through the scan lens 140. The laser beams LBa and LBb emerging from the scan lens 140 may reach the processing target 10. Each of the laser beams LBa and LBb radiated to the focal plane on the processing target 10 may be a vortex beam having a ring shape (see FIG. 6).

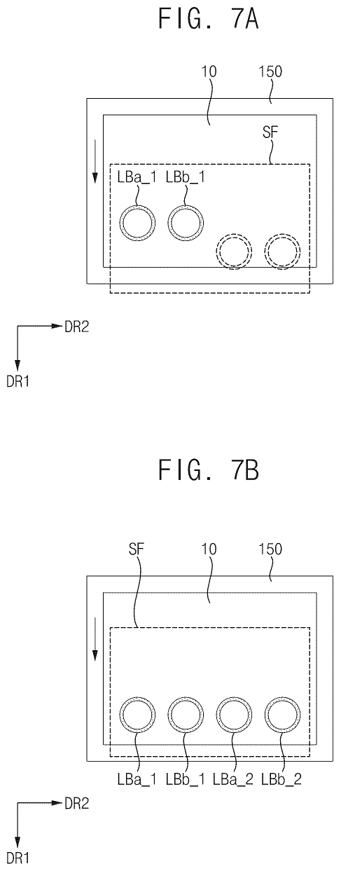

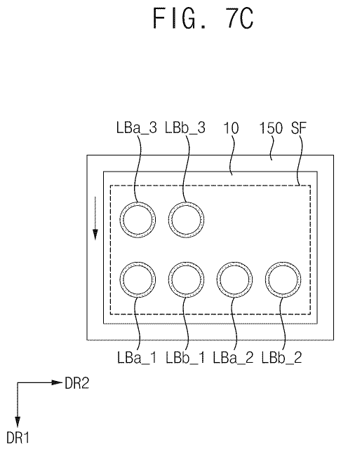

FIGS. 6, 7A, 7B, and 7C are views showing an example of a laser processing method using the laser processing apparatus of FIG. 5.

For example, FIGS. 6, 7A, 7B, and 7C may show an example of a laser processing method for implementing the shape of the processing target 10 after being processed, which is shown in FIG. 2, by using the laser processing apparatus 100a of FIG. 5.

Referring to FIGS. 2, 6, 7A, 7B, and 7C, according to an embodiment of the disclosure, a stage 150 may be moved in a direction (e.g., predetermined or selectable direction) by a stage moving part 160 while the scanner 130 performs scanning to sequentially radiate laser beams LBa_1, LBb_1, LBa_2, and LBb_2 onto different positions in the scanning field SF. The laser beams LBa_1 and LBb_1 may be radiated simultaneously, and the laser beams LBa_2 and LBb_2 may be radiated simultaneously. For example, the controller 170 may control the stage moving part 160 such that the stage 150 may be moved at a constant speed in the first direction DR1.

The controller 170 may control the scanner 130 to adjust the traveling paths of the laser beams LBa and LBb in the scanning field SF in consideration of the movement of the stage 150. The controller 170 may control an output of the first beam L1 of the laser source 110 such that the laser beams LBa and LBb may be radiated only onto desired positions in the scanning field SF.

For example, as shown in FIG. 6, the scanner 130 may adjust the traveling paths of the laser beams LBa and LBb such that the laser beams LBa_1, LBb_1 and the laser beams LBa_2 and LBb_2 may be sequentially radiated in a diagonal direction between the first direction DR1 and the second direction DR2 in the scanning field SF in consideration of a movement speed of the stage 150 in the first direction DR1. Accordingly, as shown in FIGS. 7A and 7B, the laser beams LBa_1, LBb_1, LBa_2, and LBb_2 may be radiated onto the processing target 10 in parallel with each other in the second direction DR2 as intended.

According to an embodiment of the disclosure, after the laser beams LBa_2 and LBb_2 are radiated as shown in FIG. 7C, the scanner 130 may radiate laser beams LBa_3 and LBb_3 such that the laser beams LBa_3 and LBb_3 may be adjacent to the laser beams LBa_1 and LBb_1, respectively. Next, the scanner 130 may sequentially radiate laser beams in a diagonal direction between the first direction DR1 and the second direction DR2 in the scanning field SF. The laser processing apparatus 100a may process the processing target 10 in the shape shown in FIG. 2 by repeatedly performing the process described above.

According to embodiments of the disclosure, the beam converter 120a of the laser processing apparatus 100a may convert the first beam L1, which is a Gaussian beam having a circular shape, to have an appropriate spatial phase while splitting the first beam L1 into multiple second beams L2a and L2b. Therefore, a processing time of the processing target 10 may be further reduced.

FIG. 8 is a plan view showing a display device according to an embodiment of the disclosure. FIG. 9 is a sectional view showing the display device of FIG. 8.

A display device DD shown in FIGS. 8 and 9 may be, but is not particularly limited to, one of a liquid crystal display device, an electrophoretic display device, a microelectromechanical system (MEMS) display device, an electrowetting display device, an organic light emitting display device, a micro-LED display device, a quantum dot display device, or a quantum rod display device.

Referring to FIGS. 8 and 9, according to an embodiment of the disclosure, the display device DD may include a display area DA and a non-display area NDA. The display area DA may display an image, and the non-display area NDA may not display an image. The non-display area NDA may be disposed at a periphery of the display area DA. For example, the non-display area NDA may surround the display area DA in a plan view.

According to an embodiment of the disclosure, the display area DA may include first to third emission areas EA1, EA2, and EA3 and a non-emission area NEA. Each of the first to third emission areas EA1, EA2, and EA3 may emit a light, and the non-emission area NEA may not emit a light.

The display device DD may include a first base layer BS1, a circuit layer CL, a light emitting element layer EDL, an encapsulation layer TFE, a color filter layer CFL, and a second base layer BS2. The light emitting element layer EDL may include a pixel defining layer PDL and light emitting elements ED.

The pixel defining layer PDL may define the first to third emission areas EA1, EA2, and EA3 and the non-emission area NEA. The pixel defining layer PDL may define first to third pixel openings OP1, OP2, and OP3 spaced apart from each other. The light emitting elements ED may overlap the first to third pixel openings OP1, OP2, and OP3, respectively. The first to third emission areas EA1, EA2, and EA3 may be areas corresponding to the first to third pixel openings OP1, OP2, and OP3 of the pixel defining layer PDL, respectively. The non-emission area NEA may be an area between the first to third emission areas EA1, EA2, and EA3 adjacent to each other, and may be an area corresponding to the pixel defining layer PDL. The non-emission area NEA may surround the first to third emission areas EA1, EA2, and EA3 in a plan view.

The light emitting elements ED may overlap the first to third emission areas EA1, EA2, and EA3, respectively. The light generated by the light emitting element ED may be emitted from each of the first to third emission areas EA1, EA2, and EA3.

The first to third emission areas EA1, EA2, and EA3 may emit light having different colors. For example, the first emission area EA1 may emit red light, the second emission area EA2 may emit green light, and the third emission area EA3 may emit blue light, but since such a configuration is provided for illustrative purposes, the disclosure is not limited thereto.

Although the first to third emission areas EA1, EA2, and EA3 having the same size and the same shape have been shown in FIG. 8 as being arranged, such a configuration is provided for illustrative purposes, so that the disclosure is not limited thereto. For example, the first to third emission areas EA1, EA2, and EA3 may have different sizes and different shapes, and may be arranged in various shapes. For example, each of the first to third emission areas EA1, EA2, and EA3 may have various shapes such as a rectangle, a polygon, a circle, or an ellipse.

According to an embodiment of the disclosure, all the light emitting elements ED disposed in the first to third emission areas EA1, EA2, and EA3, respectively, may emit a white light. The color filter layer CFL may include first to third color filters CF1, CF2, and CF3 overlapping the first to third emission areas EA1, EA2, and EA3, respectively. For example, the first color filter CF1 may be a red color filter, the second color filter CF2 may be a green color filter, and the third color filter CF3 may be a blue color filter. Accordingly, the first emission area EA1 may emit red light, the second emission area EA2 may emit green light, and the third emission area EA3 may emit blue light.

According to another embodiment of the disclosure, the light emitting elements ED disposed in the first to third emission areas EA1, EA2, and EA3, respectively, may emit light having different colors. For example, the light emitting element ED disposed in the first emission area EA1 may emit red light, the light emitting element ED disposed in the second emission area EA2 may emit green light, and the light emitting element ED disposed in the third emission area EA3 may emit blue light.

Hereinafter, a structure of the display device DD will be described in more detail focusing on an embodiment of the disclosure in which all the light emitting elements ED disposed in the first to third emission areas EA1, EA2, and EA3, respectively, emits a white light.

The first base layer BS1 may be a member configured to provide a base surface on which the light emitting element layer EDL is disposed. The first base layer BS1 may be a glass substrate, a metal substrate, a plastic substrate, the like, or a combination thereof. The first base layer BS1 may be an inorganic layer, an organic layer, a composite material layer, or a combination thereof.

The circuit layer CL may be disposed on the first base layer BS1. The circuit layer CL may include multiple transistors (not shown). Each of the transistors may include a control electrode, an input electrode, and an output electrode. For example, the circuit layer CL may include a switching transistor and a driving transistor for driving each of the light emitting elements ED.

The pixel defining layer PDL may be disposed on the circuit layer CL. According to an embodiment of the disclosure, the pixel defining layer PDL may be formed of a polymer resin. For example, the pixel defining layer PDL may include a polyimide-based resin, a polyacrylate-based resin, or the like. According to an embodiment of the disclosure, the pixel defining layer PDL may include a light absorbing material, or may include a black pigment or a black dye.

Each of the light emitting element ED may include: a first electrode EL1 and a second electrode EL2, which are facing each other; and multiple light emitting structures OL1, OL2, and OL3 stacked on each other in a thickness direction between the first electrode EL1 and the second electrode EL2. Each of the light emitting elements ED may further include charge generation layers CGL1 and CGL2 disposed between the light emitting structures OL1, OL2, and OL3 adjacent to each other, respectively. Each of the light emitting structures OL1, OL2, and OL3 may include an electron transport area, a light emitting layer, and a hole transport area, which will be described below. In other words, each of the light emitting elements ED may be a light emitting element having a tandem structure and including multiple light emitting structures, each of which includes a light emitting layer.

Although each of the light emitting elements ED has been shown in FIG. 9 as including three light emitting structures OL1, OL2, and OL3 and two charge generation layers CGL1 and CGL2, such a configuration may be provided for illustrative purposes, so that the disclosure is not limited thereto. For example, each of the light emitting elements ED may include two light emitting structures and a charge generation layer (e.g., single charge generation layer), or may include at least four light emitting structures and at least three charge generation layers.

According to an embodiment of the disclosure, structures of the light emitting elements ED disposed in the first to third emission areas EA1, EA2, and EA3, respectively, may be substantially identical to each other. According to another embodiment of the disclosure, the structures of the light emitting elements ED disposed in the first to third emission areas EA1, EA2, and EA3, respectively, may be different from each other. Hereinafter, the structures of the light emitting elements ED will be described in more detail focusing on an embodiment of the disclosure in which the structures of the light emitting elements ED disposed in the first to third emission areas EA1, EA2, and EA3, respectively, are substantially identical to each other.

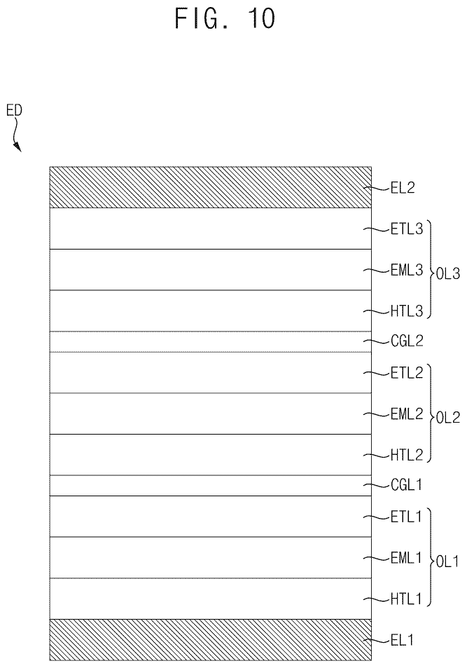

FIG. 10 is a sectional view showing a light emitting element included in the display device of FIG. 9.

Referring to FIGS. 9 and 10, each of the light emitting elements ED may have a structure in which the first electrode EL1, a first light emitting structure OL1, a first charge generation layer CGL1, a second light emitting structure OL2, a second charge generation layer CGL2, a third light emitting structure OL3, and the second electrode EL2 may be sequentially stacked on each other in a thickness direction. The first light emitting structure OL1may include a first hole transport layer HTL1, a first light emitting layer EML1, and a first electron transport layer ETL1. According to an embodiment of the disclosure, the first light emitting layer EML1 may be a red light emitting layer configured to emit red light. The second light emitting structure OL2 may include a second hole transport layer HTL2, a second light emitting layer EML2, and a second electron transport layer ETL2. According to an embodiment of the disclosure, the second light emitting layer EML2 may be a green light emitting layer configured to emit green light. The third light emitting structure OL3 may include a third hole transport layer HTL3, a third light emitting layer EML3, and a third electron transport layer ETL3. According to an embodiment of the disclosure, the third light emitting layer EML3 may be a blue light emitting layer configured to emit blue light. Since each of the light emitting elements ED includes all of the first light emitting layer EML1 configured to emit red light, the second light emitting layer EML2 configured to emit green light, and the third light emitting layer EML3 configured to emit blue light, each of the light emitting elements ED may emit a white light.

According to an embodiment of the disclosure, as described above, the light emitting element ED disposed in the first emission area EA1 may emit red light, the light emitting element ED disposed in the second emission area EA2 may emit green light, and the light emitting element ED disposed in the third emission area EA3 may emit blue light. All of the first to third light emitting layers EML1, EML2, and EML3 included in the light emitting element ED disposed in the first emission area EA1 may be red light emitting layers configured to emit red light. All the first to third light emitting layers EML1, EML2, and EML3 included in the light emitting element ED disposed in the second emission area EA2 may be green light emitting layers configured to emit green light. All the first to third light emitting layers EML1, EML2, and EML3 included in the light emitting element ED disposed in the third emission area EA3 may be blue light emitting layers configured to emit blue light.

According to an embodiment of the disclosure, each of the first to third light emitting structures OL1, OL2, and OL3 may further include an electron injection layer, a hole blocking layer, a hole injection layer, an electron blocking layer, a buffer layer, and the like.

The first charge generation layer CGL1 may be disposed between the first light emitting structure OL1 and the second light emitting structure OL2. The first charge generation layer CGL1 may promote movement of holes and/or charges between the first and second light emitting structures OL1 and OL2. The second charge generation layer CGL2 may be disposed between the second light emitting structure OL2 and the third light emitting structure OL3. The second charge generation layer CGL2 may promote movement of holes and/or charges between the second and third light emitting structures OL2 and OL3. According to an embodiment of the disclosure, each of the first and second charge generation layers CGL1 and CGL2 may include a p-type charge generation layer and an n-type charge generation layer, and may have an NP junction structure. For example, the p-type charge generation layer may include an organic dopant, and the n-type charge generation layer may include a metal dopant.

According to an embodiment of the disclosure, as shown in FIG. 9, the light emitting structures OL1, OL2, and OL3 and the charge generation layers CGL1 and CGL2 disposed in the first to third emission areas EA1, EA2, and EA3 may be physically separated from the light emitting structures OL1, OL2, and OL3 and the charge generation layers CGL1 and CGL2 disposed in the first to third emission areas EA1, EA2, and EA3 adjacent thereto by a groove GV. For example, the groove GV may have a mesh shape in a plan view (see FIG. 11B). In particular, the first charge generation layers CGL1 disposed in the first to third emission areas EA1, EA2, and EA3 adjacent to each other, respectively, may be physically separated from each other by the groove GV. Similarly, the second charge generation layers CGL2 disposed in the first to third emission areas EA1, EA2, and EA3 adjacent to each other, respectively, may be physically separated from each other by the groove GV. For example, stacked structures of the light emitting structures OL1, OL2, and OL3 and the charge generation layers CGL1 and CGL2 disposed in the first to third emission areas EA1, EA2, and EA3, respectively, may have a shape of multiple island patterns spaced apart from each other in a plan view (see FIG. 11B). Accordingly, a lateral leakage between the light emitting elements ED disposed in the first to third emission areas EA1, EA2, and EA3, respectively, may be prevented. Therefore, display quality of the display device DD may be improved. As will be described below, the grooves GV may be formed through laser processing by using a laser processing apparatus.

Referring again to FIG. 9, the second electrode EL2 may be disposed on the third light emitting structure OL3. The second electrode EL2 may be disposed over an entire area of the first to third emission areas EA1, EA2, and EA3 and the non-emission area NEA. The second electrodes EL2 included in the light emitting elements ED disposed in the first to third emission areas EA1, EA2, and EA3, respectively, may be physically connected to each other.

The encapsulation layer TFE may be disposed on the second electrode EL2. The encapsulation layer TFE may be disposed over an entire area of the first to third emission areas EA1, EA2, and EA3 and the non-emission area NEA. The encapsulation layer TFE may seal the light emitting elements ED. The encapsulation layer TFE may prevent impurities, moisture, external air, and the like from penetrating into the light emitting elements ED. The encapsulation layer TFE may include at least one inorganic encapsulation layer (e.g., single inorganic encapsulation layer) and at least one organic encapsulation layer (e.g., single organic encapsulation layer).

The color filter layer CFL may be disposed on the encapsulation layer TFE. The color filter layer CFL may include first to third color filters CF1, CF2, and CF3 overlapping the first to third emission areas EA1, EA2, and EA3, respectively, and a light blocking member BM overlapping the non-emission area NEA.

For example, the first color filter CF1 may be a red color filter configured to transmit red light. A white light emitted from the light emitting element ED disposed in the first emission area EA1 may be filtered into red light by the first color filter CF1 and emitted to an outside. Accordingly, the first emission area EA1 may emit red light.

For example, the second color filter CF2 may be a green color filter configured to transmit green light. A white light emitted from the light emitting element ED disposed in the second emission area EA2 may be filtered into green light by the second color filter CF2 and emitted to the outside. Accordingly, the second emission area EA2 may emit green light.

For example, the third color filter CF3 may be a blue color filter configured to transmit blue light. A white light emitted from the light emitting element ED disposed in the third emission area EA3 may be filtered into blue light by the third color filter CF3 and emitted to the outside. Accordingly, the third emission area EA3 may emit blue light.

The light blocking member BM may overlap the non-emission area NEA. The light blocking member BM may be disposed between the first to third color filters CF1, CF2, and CF3 adjacent to each other. The light blocking member BM may block light to prevent color mixing between the first to third emission areas EA1, EA2, and EA3. For example, the light blocking member BM may include a black matrix. For another example, the light blocking member BM may have a structure in which the first to third color filters CF1, CF2, and CF3 may be stacked on each other in the thickness direction.

The second base layer BS2 may be disposed on the color filter layer CFL. The second base layer BS2 may be a member configured to provide a base surface on which the color filter layer CFL may be disposed. The second base layer BS2 may be a glass substrate, a metal substrate, a plastic substrate, the like, or a combination thereof. The second base layer BS2 may be an inorganic layer, organic layer, or a composite material layer, or a combination thereof.

FIGS. 11A, 11B, 12, 13, and 14 are views showing an example of a method for manufacturing a display device according to an embodiment of the disclosure.

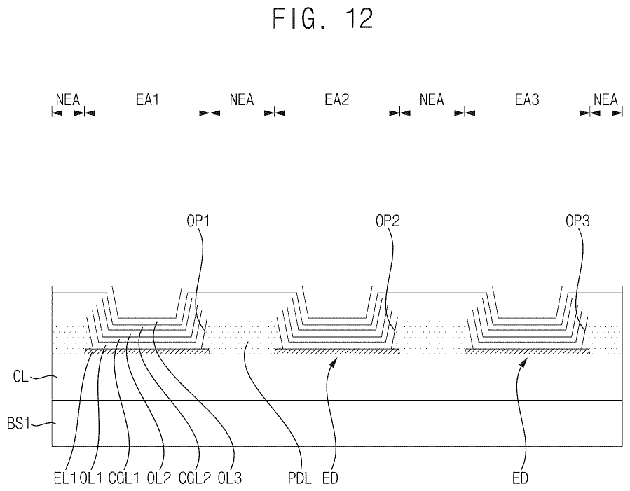

FIGS. 11A and 11B may be plan views for describing an example of a method for manufacturing the display device DD of FIGS. 8 and 9 by using the laser processing apparatus 100 of FIG. 1 (or the laser processing apparatus 100a of FIG. 5). FIGS. 12, 13, and 14 may be sectional views for describing an example of a method for manufacturing the display device DD of FIGS. 8 and 9 by using the laser processing apparatus 100 of FIG. 1 (or the laser processing apparatus 100a of FIG. 5). Each of the sectional views of FIGS. 12, 13, and 14 may correspond to the sectional view of FIG. 9. Hereinafter, redundant descriptions corresponding to contents described with reference to FIGS. 8 and 9 will be omitted or simplified.

Referring to FIG. 12, a circuit layer CL may be formed on a first base layer BS1. First electrodes EL1 may be formed on the circuit layer CL to overlap first to third emission areas EA1, EA2, and EA3, respectively. The first electrodes EL1 disposed in the first to third emission areas EA1, EA2, and EA3, respectively, may be spaced apart from each other.

A pixel defining layer PDL overlapping a non-emission area NEA and having first to third pixel openings OP1, OP2, and OP3 overlapping the first to third emission areas EA1, EA2, and EA3, respectively, may be formed on the circuit layer CL and the first electrodes EL1. First, a preliminary pixel defining layer may be formed over an entire area of the circuit layer CL and the first electrodes EL1. The pixel defining layer PDL having the first to third pixel openings OP1, OP2, and OP3 overlapping the first to third emission areas EA1, EA2, and EA3, respectively, may be formed by partially removing the preliminary pixel defining layer. The first to third pixel openings OP1, OP2, and OP3 may overlap the first to third emission areas EA1, EA2, and EA3, respectively. The pixel defining layer PDL may cover a peripheral portion of each of the first electrodes EL1, and expose a central portion of each of the first electrodes EL1.

A first light emitting structure OL1, a first charge generation layer CGL1, a second light emitting structure OL2, a second charge generation layer CGL2, and a third light emitting structure OL3 may be sequentially stacked on each other and formed on the first electrodes EL1 and the pixel defining layer PDL. Hereinafter, a structure in which the first light emitting structure OL1, the first charge generation layer CGL1, the second light emitting structure OL2, the second charge generation layer CGL2, and the third light emitting structure OL3 may be stacked on each other in a thickness direction may be referred to as a stacked structure. The stacked structure may be formed over an entire area of the first to third emission areas EA1, EA2, and EA3 and the non-emission area NEA. The stacked structure may overlap the first to third pixel openings OP1, OP2, and OP3 and the pixel defining layer PDL.

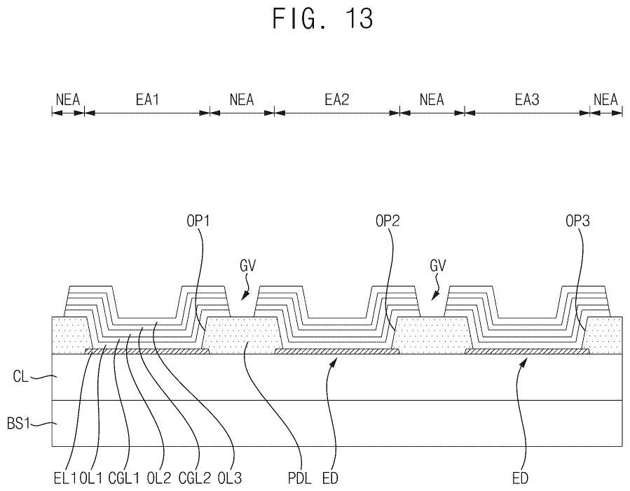

Next, as shown in FIGS. 11A, 11B, and 13, a groove GV may be formed in the stacked structure to overlap the non-emission area NEA. According to an embodiment of the disclosure, as shown in FIG. 11A, the groove GV may be formed in the stacked structure by radiating multiple ring-shaped laser beams LB onto the stacked structure by using the laser processing apparatus 100 of FIG. 1 or the laser processing apparatus 100a of FIG. 5.

The groove GV may be formed through at least the third light emitting structure OL3, the second charge generation layer CGL2, the second light emitting structure OL2, and the first charge generation layer CGL1. For example, as shown in FIG. 13, the groove GV may be formed through the third light emitting structure OL3, the second charge generation layer CGL2, the second light emitting structure OL2, the first charge generation layer CGL1, and the first light emitting structure OL1 in the thickness direction. For example, the groove GV may expose an upper surface of the pixel defining layer PDL.

According to an embodiment of the disclosure, as shown in FIG. 11A, the ring-shaped laser beams LB may be radiated to surround the first to third emission areas EA1, EA2, and EA3, respectively. In other words, each of the ring-shaped laser beams LB may be radiated to surround a corresponding one of the first to third emission areas EA1, EA2, and EA3. Each of the ring-shaped laser beams LB may be radiated to overlap the non-emission area NEA without overlapping the first to third emission areas EA1, EA2, and EA3. For example, due to a high resolution of the display device DD, a radius WO of each of the ring-shaped laser beams LB may be less than or equal to about 5.2 μm, and a width WB of each of the ring-shaped laser beams LB may be less than or equal to about 2 μm. However, since such a configuration may be provided for illustrative purposes, the radius WO and the width WB of the laser beam LB may be variously modified according to sizes of the first to third emission areas EA1, EA2, and EA3 and a width of the non-emission area NEA.

According to an embodiment of the disclosure, as shown in FIG. 11A, the ring-shaped laser beams LB may be radiated to partially overlap each other. According to another embodiment of the disclosure, the ring-shaped laser beams LB may be radiated so as to be spaced apart from each other.

The ring-shaped laser beams LB may be radiated onto the stacked structure by a method that is similar to the laser processing method described with reference to FIGS. 2, 3, 4A, 4B, 4C, 4D, and 4E or the laser processing method described with reference to FIGS. 2, 6, and 7A to 7E.

As shown in FIGS. 11B and 13, a groove GV having a mesh shape may be formed in the stacked structure by radiating the ring-shaped laser beams LB onto the stacked structure. Accordingly, the stacked structure may include multiple island patterns spaced apart from each other. Each of the island patterns may overlap a corresponding emission area among the first to third emission areas EA1, EA2, and EA3. For example, a size of each of the island patterns may be greater than a size of the corresponding emission area among the first to third emission areas EA1, EA2, and EA3.

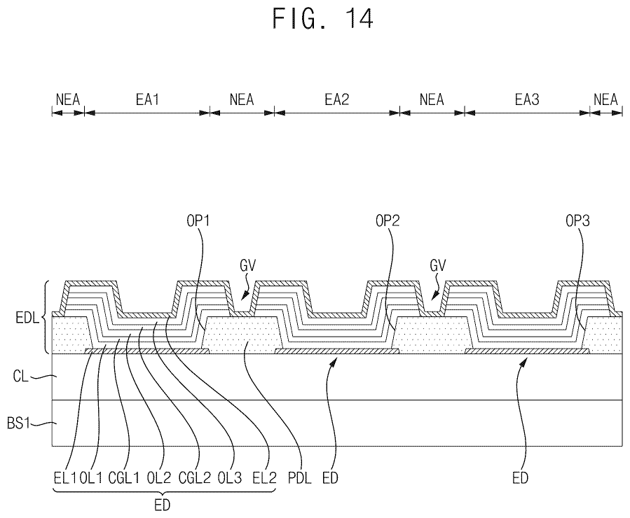

Next, as shown in FIG. 14, a second electrode EL2 may be formed on the pixel defining layer PDL and the stacked structure. The second electrode EL2 may be formed over an entire area of the first to third emission areas EA1, EA2, and EA3 and the non-emission area NEA. Next, an encapsulation layer TFE, a color filter layer CFL, and a second base layer BS2 may be formed, so that the display device DD of FIG. 9 may be manufactured.

According to embodiments of the disclosure, the first charge generation layers CGL1 disposed in the first to third emission areas EA1, EA2, and EA3 adjacent to each other, respectively, may be physically separated from each other by the groove GV. Similarly, the second charge generation layers CGL2 disposed in the first to third emission areas EA1, EA2, and EA3 adjacent to each other, respectively, may be physically separated from each other by the groove GV. Therefore, a lateral leakage between light emitting elements ED disposed in the first to third emission areas EA1, EA2, and EA3, respectively, may be prevented or reduced. Therefore, display quality of the display device DD may be improved.

In order to form the groove GV in the stacked structure, the laser beams LB may be radiated to the stacked structure by using the laser processing apparatus 100 of FIG. 1 (or the laser processing apparatus 100a of FIG. 5). The laser processing apparatus 100 may rapidly radiate the laser beams LB, which are ring-shaped vortex beams, to the stacked structure. Therefore, a processing time of the stacked structure may be reduced, so that a manufacturing cost and a manufacturing time of the display device DD may be reduced.

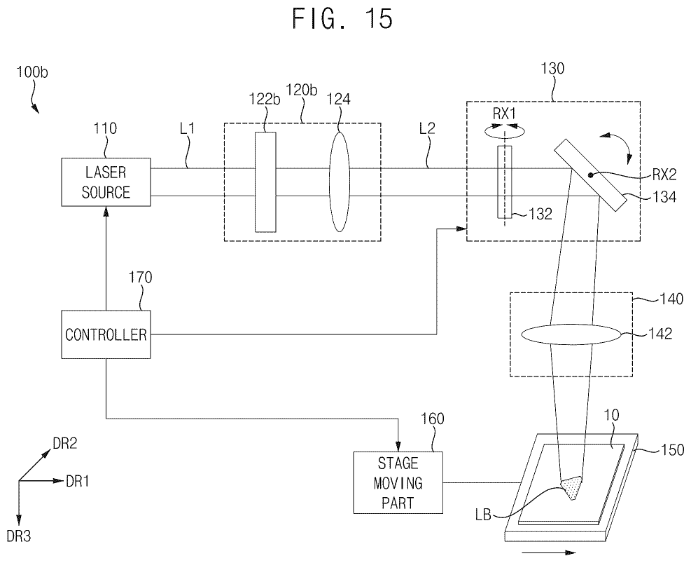

FIG. 15 is a view schematically showing a laser processing apparatus according to an embodiment of the disclosure.

A laser processing apparatus 100b of FIG. 15 may be substantially identical to the laser processing apparatus 100 of FIG. 1 except for a configuration of a diffractive optical element 122b. Therefore, redundant descriptions will be omitted or simplified.

Referring to FIG. 15, according to an embodiment of the disclosure, a laser processing apparatus 100b may include a laser source 110, a beam converter 120b, a scanner 130, and a scan lens 140.

A first beam L1 emitted from the laser source 110 may be a Gaussian beam having a circular shape. The first beam L1 may be a single beam. According to an embodiment of the disclosure, the beam converter 120b may transform a spatial phase of the first beam L1, which is a Gaussian beam having a circular shape, to convert the first beam L1 into a second beam L2 having an appropriate spatial phase. The second beam L2 may have an appropriate spatial phase upon passing through the scanner 130 and the scan lens 140 and being finally radiated onto a focal plane on a processing target 10 so that a cross-sectional shape may be a triangle with either angled corners or rounded corners. However, since such a configuration may be provided for illustrative purposes, the disclosure is not limited thereto, and the second beam L2 may have an appropriate spatial phase to pass through the scanner 130 and the scan lens 140 and finally radiated to a focal plane on the processing target 10 in various shapes such as a rectangle with angled or rounded corners, a triangular star, and a rectangular star.

According to an embodiment of the disclosure, the beam converter 120b may include a diffractive optical element 122b and a relay lens 124. The diffractive optical element 122b may be configured to diffract the first beam L1, which is a Gaussian beam having a circular shape, to convert the first beam L1 into the second beam L2 having the spatial phase. According to an embodiment of the disclosure, the diffractive optical element 122b may be configured to diffract the first beam L1, which is a Gaussian beam having a circular shape, to convert and split the first beam L1 into second beams, each of which has the spatial phase. According to an embodiment of the disclosure, the diffractive optical element 122b may be replaced with a spatial light modulator (SLM). According to an embodiment of the disclosure, the beam converter 120b may produce multiple Gaussian beams to overlap each other to convert the Gaussian beams into a second beam L2. The relay lens 124 may relay the second beam L2 to the scanner 130.

The second beam L2 may be incident on the scanner 130. The scanner 130 may variously adjust traveling paths of laser beams in a scanning field.

The second beam L2 that has passed through the scanner 130 to have a changed path may be incident on the scan lens 140. The scan lens 140 may adjust a focal point of the second beam L2 emerging from the scanner 130 to focus the second beam L2 on the scanning field on the processing target 10.

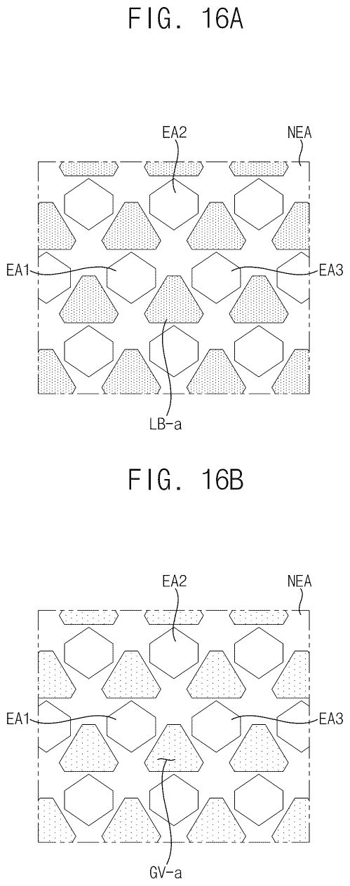

The second beam L2 emerging from the scanner 130 may be converted into a laser beam LB while passing through the scan lens 140. The laser beam LB emerging from the scan lens 140 may reach the processing target 10. The laser beam LB radiated to the focal plane on the processing target 10 may have a shape of a triangle with angled corners (or a shape of a triangle with rounded corners) (see FIGS. 16A and 16B). However, since such a configuration may be provided for illustrative purposes, the disclosure is not limited thereto, and the laser beam LB may have various shapes such as a rectangle with angled or rounded corners, a triangular star, and a rectangular star.

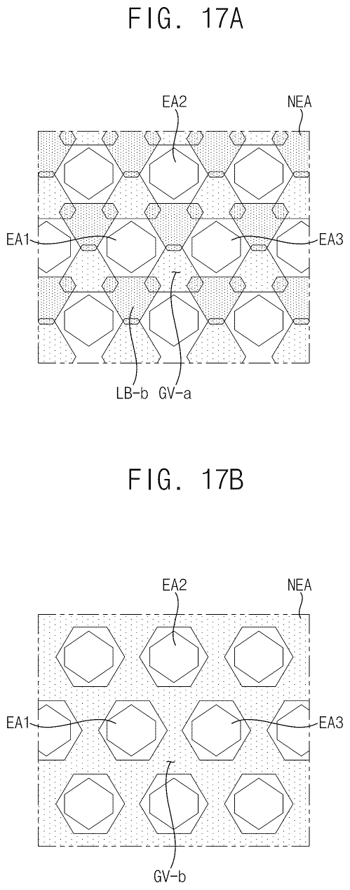

FIGS. 16A, 16B, 17A, and 17B are views showing an example of a method for manufacturing a display device according to an embodiment of the disclosure.

FIGS. 16A, 16B, 17A, and 17B may be plan views for describing an example of a method for manufacturing the display device DD of FIGS. 8 and 9 by using the laser processing apparatus 100b of FIG. 15. A method for manufacturing the display device DD of FIGS. 16A, 16B, 17A, and 17B may be substantially identical or similar to the method for manufacturing the display device DD described with reference to FIGS. 11A, 11B, 12, 13, and 14 except for forming of a groove GV-b by radiating laser beams LB-a and LB-b to the stacked structure. Therefore, redundant descriptions corresponding to contents described with reference to FIGS. 11A, 11B, 12, 13, and 14 will be omitted or simplified.

According to an embodiment of the disclosure, as shown in FIG. 16A, preliminary grooves GV-a may be formed in the stacked structure by radiating multiple first laser beams LB-a in a shape of a triangle with angled corners (or a shape of a triangle with rounded corners) onto the stacked structure by using the laser processing apparatus 100b of FIG. 15.

According to an embodiment of the disclosure, as shown in FIG. 16A, each of the first laser beams LB-a may be radiated between the first to third emission areas EA1, EA2, and EA3 adjacent to each other. For example, each of the first laser beams LB-a may be radiated between three emission areas adjacent to each other. Each of the first laser beams LB-a may be radiated to overlap the non-emission area NEA without overlapping the first to third emission areas EA1, EA2, and EA3.

Multiple first laser beams LB-a having a shape of a triangle with angled corners may be radiated onto the stacked structure by a method that may be similar to the laser processing method described with reference to FIGS. 2, 3, 4A, 4B, 4C, 4D, and 4E or the laser processing method described with reference to FIGS. 2, 6, and 7A to 7C.

As shown in FIG. 16B, even in case that the preliminary groove GV-a may be formed in the stacked structure by radiating the first laser beams LB-a in a shape of a triangle with angled corners onto the stacked structure, the stacked structure may have a mesh structure connected to each other. In order to form the stacked structure to include multiple island patterns spaced apart from each other, as shown in FIGS. 17A and 17B, multiple second laser beams LB-b having a shape in which the first laser beam LB-a that has been radiated may be inverted may be radiated onto the stacked structure.

According to an embodiment of the disclosure, as shown in FIG. 17A, each of the second laser beams LB-b may be radiated between the first to third emission areas EA1, EA2, and EA3 adjacent to each other. Each of the second laser beams LB-b may have a shape in which the first laser beam LB-a that has been radiated may be inverted (e.g., rotated about 180 degrees about a thickness direction). For example, each of the second laser beams LB-b may be radiated between three emission areas adjacent to each other and between three preliminary grooves GV-a adjacent to each other. Each of the second laser beams LB-b may be radiated to overlap the non-emission area NEA without overlapping the first to third emission areas EA1, EA2, and EA3.

According to an embodiment of the disclosure, in order to radiate the second laser beams LB-b having a shape in which the first laser beam LB-a that has been radiated may be inverted (e.g., rotated about 180 degrees about the thickness direction) onto the stacked structure, after the first laser beams LB-a may be radiated, a stage 150 on which the stacked structure may be seated may be rotated 1 about 80 degrees about the third direction DR3 (see FIG. 15). Next, the stage 150 may be aligned, and the second laser beams LB-b may be radiated onto the stacked structure such that each of the second laser beams LB-b may be radiated between three emission areas adjacent to each other and between three preliminary grooves GV-a adjacent to each other.

According to an embodiment of the disclosure, as shown in FIGS. 16A and 17A, the first laser beams LB-a and the second laser beams LB-b, which have mutually inverted shapes and are adjacent to each other, may be radiated to partially overlap each other. Accordingly, as shown in FIG. 17B, a groove GV-b having a mesh shape may be formed in the stacked structure. The stacked structure may include multiple island patterns spaced apart from each other. In other words, the second laser beams LB-b having a shape in which the first laser beam LB-a may be inverted may be radiated so that the preliminary grooves GV-a formed by the first laser beams LB-a that have been radiated may be connected to each other to form the groove GV-b having a mesh shape. Each of the island patterns may overlap a corresponding emission area among the first to third emission areas EA1, EA2, and EA3. For example, a size of each of the island patterns may be greater than a size of the corresponding emission area among the first to third emission areas EA1, EA2, and EA3.

Next, a second electrode EL2, an encapsulation layer TFE, a color filter layer CFL, and a second base layer BS2 may be formed on a pixel defining layer PDL and the stacked structure, so that the display device DD of FIG. 9 may be manufactured.

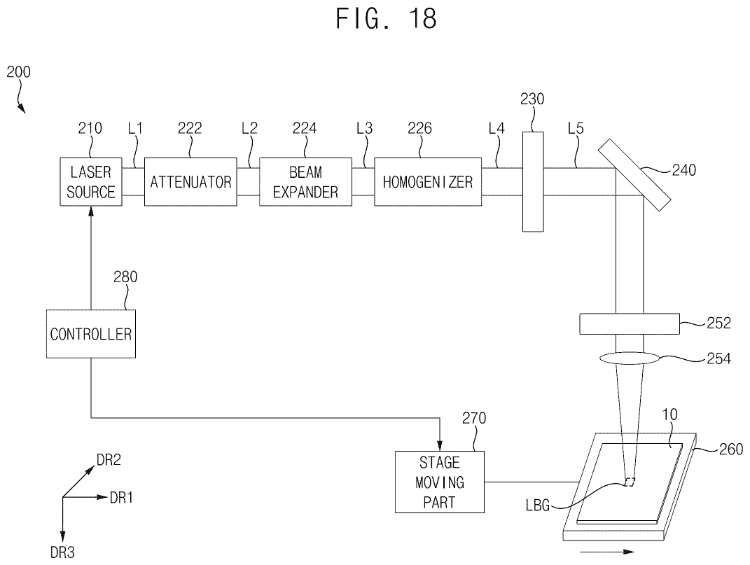

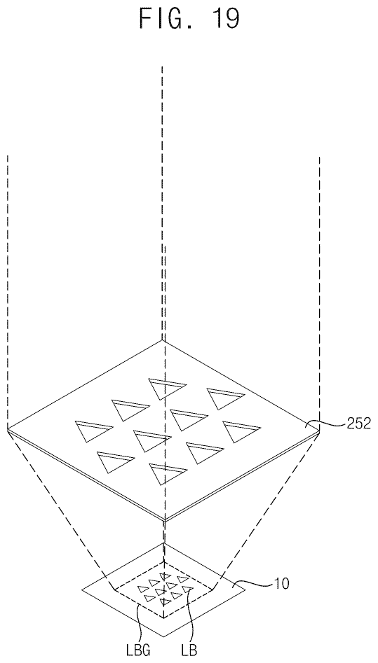

FIGS. 18 and 19 are views schematically showing a laser processing apparatus according to an embodiment of the disclosure.

Referring to FIGS. 18 and 19, according to an embodiment of the disclosure, a laser processing apparatus 200 may include a laser source 210, a beam attenuator 222, a beam expander 224, a beam homogenizer 226, a diffractive optical element 230, a mirror 240, a mask 252, a projection lens 254, a stage 260, a stage moving part 270, and a controller 280.

The laser processing apparatus 200 may process a processing target 10 by radiating a laser beam LBG including multiple laser beam patterns LB to the processing target 10. The processing target 10 may be seated on a seating surface of the stage 260.

The laser source 210 may be various laser generation devices. The laser source 210 may emit a first beam L1. The first beam L1 emitted from the laser source 210 may be a Gaussian beam having a circular shape.

The beam attenuator 222 may produce a second beam L2 obtained by attenuating an intensity of the first beam L1 emerging from the laser source 210. The beam expander 224 may produce a third beam L3 obtained by enlarging a size of the second beam L2 emerging from the beam attenuator 222. The beam homogenizer 226 may produce a fourth beam L4 obtained by homogenizing the third beam L3 emerging from the beam expander 224 such that the third beam L3 has uniform overall distribution.

The diffractive optical element 230 may produce a fifth beam L5 by diffracting the fourth beam L4 in order to compensate for a reduction in distortion of a laser beam passing through the mask 252. The mirror 240 may change a traveling direction of the fifth beam L5 emerging from the diffractive optical element 230 toward the processing target 10.

The fifth beam L5 reflected by the mirror 240 may be incident on the mask 252. As shown in FIG. 19, the mask 252 may define multiple openings that form a pattern (e.g., predetermined or selectable pattern). For example, each of the openings may have a shape of a triangle (or a shape of a triangle with angled or rounded corners). The fifth beam L5 may be converted into the laser beam LBG including the laser beam patterns LB of a pattern (e.g., predetermined or selectable pattern) while passing through the openings of the mask 252. For example, each of the laser beam patterns LB may have a shape of a triangle with angled corners (or a shape of a triangle with rounded corners).

The projection lens 254 may focus the laser beam LBG that has passed through the mask 252 to radiate the focused laser beam LBG onto the processing target 10 seated on the seating surface of the stage 260. The stage 260 may be moved in a direction (e.g., predetermined or selectable direction) by the stage moving part 270.

The controller 280 may control overall operations of the laser source 210 and the stage moving part 270. For example, the laser source 210 may receive a fourth control signal from the controller 280 to adjust an output, a wavelength, and the like of the first beam L1. The stage moving part 270 may receive a fifth control signal from the controller 280 to transfer the processing target 10 in a designated direction.

According to the laser processing apparatus 200 of FIGS. 18 and 19, the laser beam patterns LB of a pattern (e.g., predetermined or selectable pattern) may be simultaneously radiated onto the processing target 10. For example, each of the laser beam patterns LB may have a shape of a triangle with angled corners (or a shape of a triangle with rounded corners). According to an embodiment of the disclosure, by using the laser processing apparatus 200 of FIGS. 18 and 19, the display device DD may be manufactured by using a method that may be similar to the method for manufacturing the display device DD described with reference to FIGS. 16A, 16B, 17A, and 17B. The laser processing apparatus 200 may rapidly radiate the laser beam patterns LB to the stacked structure. Therefore, a processing time of the stacked structure may be reduced, so that a manufacturing cost and a manufacturing time of the display device DD may be reduced.

Although embodiments and implementations have been described herein, other embodiments and modifications will be apparent from this description. Accordingly, the disclosure is not limited to such embodiments, but rather to the broader scope of the appended claims and various obvious modifications and equivalent arrangements as would be apparent to a person of ordinary skill in the art.

What is claimed is:

1. A laser processing apparatus comprising:
a stage on which a processing target is seated;
a laser source that generates a first beam;
a beam converter that converts the first beam into a second beam by transforming a spatial phase of the first beam;
a scanner that changes a traveling direction of the second beam toward the processing target and that adjusts a traveling path of the second beam;
a scan lens that focuses the second beam onto the processing target by adjusting a focal point of the second beam emerging from the scanner; and
a stage moving part that moves the stage.

2. The laser processing apparatus of claim 1, wherein
the first beam is a Gaussian beam having a circular shape, and
the second beam passes through the scanner and the scan lens and onto a focal plane on the processing target in a form of a vortex beam having a ring shape.

3. The laser processing apparatus of claim 1, wherein
the first beam is a Gaussian beam having a circular shape, and
the second beam passes through the scanner and the scan lens and onto a focal plane on the processing target in a shape of a triangle with angled corners or a triangle with rounded corners.

4. The laser processing apparatus of claim 1, wherein the beam converter is configured to convert and split the first beam into a plurality of second beams.

5. The laser processing apparatus of claim 1, wherein the stage moving part to move the stage while the scanner performs scanning to sequentially radiate the second beam onto different positions on the processing target.

6. A method for manufacturing a display device, the method comprising:
forming a first electrode on a circuit layer to overlap each of first, second, and third emission areas;
forming a pixel defining layer on the circuit layer and the first electrode, the pixel defining layer overlapping a non-emission area between the first, second, and third emission areas adjacent to each other, and the pixel defining layer having first, second, and third pixel openings overlapping the first, second, and third emission areas, respectively;
forming a stacked structure in the first, second, and third pixel openings and on the pixel defining layer, the stacked structure including a first light emitting structure, at least one charge generation layer, and a second light emitting structure are sequentially stacked on each other;
forming a groove in the stacked structure that overlaps the non-emission area by radiating laser beams onto the stacked structure; and
forming a second electrode on the stacked structure.

7. The method of claim 6, wherein the forming of the groove includes radiating ring-shaped laser beams onto the stacked structure.

8. The method of claim 7, wherein each of the ring-shaped laser beams is radiated to overlap the non-emission area without overlapping the first, second, and third emission areas.

9. The method of claim 7, wherein each of the ring-shaped laser beams is radiated to surround a corresponding one of the first, second, and third emission areas.

10. The method of claim 7, wherein the ring-shaped laser beams are radiated to partially overlap each other.

11. The method of claim 6, wherein the forming of the groove includes:
forming preliminary grooves by radiating first laser beams having a shape of a triangle with angled corners or a triangle with rounded corners onto the stacked structure to overlap the non-emission area; and
radiating second laser beams having a shape in which the first laser beam is inverted onto the stacked structure to overlap the non-emission area.

12. The method of claim 11, wherein each of the first laser beams and the second laser beams is radiated to overlap the non-emission area without overlapping the first, second, and third emission areas.

13. The method of claim 11, wherein each of the first laser beams is radiated between the first, second, and third emission areas adjacent to each other.

14. The method of claim 13, wherein each of the second laser beams is radiated between the first, second, and third emission areas adjacent to each other and between the preliminary grooves adjacent to each other.

15. The method of claim 11, wherein the first laser beams and the second laser beams are radiated to partially overlap each other.

16. The method of claim 6, wherein the groove has a mesh shape in a plan view.

17. The method of claim 6, wherein the groove is formed through the first light emitting structure, the at least one charge generation layer, and the second light emitting structure in a thickness direction.

18. The method of claim 6, wherein the groove exposes an upper surface of the pixel defining layer.

19. The method of claim 6, wherein
the at least one charge generation layer includes a plurality of charge generation layers, and
the plurality of charge generation layers disposed in the first, second and third emission areas adjacent to each other, respectively, are physically separated from each other by the groove.

20. The method of claim 6, wherein each of the first light emitting structure and the second light emitting structure includes a light emitting layer.
